(19) United States
(12) Patent Application Publication
(10) Pub. No.: US 2023/0386897 A1
(43) Pub. Date: Nov. 30, 2023

(54) ANGLED CONTACT WITH A NEGATIVE TAPERED PROFILE

(71) Applicant: INTERNATIONAL BUSINESS MACHINES CORPORATION, ARMONK, NY (US)

(72) Inventors: Oleg Gluschenkov, Tannersville, NY (US); Yasir Sulehria, Niskayuna, NY (US); Ruilong Xie, Niskayuna, NY (US); Kai Zhao, Albany, NY (US)

(21) Appl. No.: 17/664,671

(22) Filed: May 24, 2022

(51) Int. Cl. H01L 21/768; H01L 21/311; H01L 29/40; H01L 29/417; H01L 23/522

(52) U.S. Cl. CPC H01L 21/76804; H01L 21/311; H01L 29/401; H01L 29/41725; H01L 23/5226; H01L 29/0847

(57) ABSTRACT

A microelectronics device including a gate region located adjacent to a source/drain region. A contact located above the source/drain region, where the contact has a bottom section, a middle section and top section, wherein the sidewalls of the bottom section, the middle section, and the top section of the contact are tapered towards a center Y-axis of the contact. A gate contact located above the gate region, where the gate contact has tapered sidewalls towards a center Y-axis of the gate contact. The gate contact is adjacent to the contact. The tapering of the sidewalls of the gate contact is inverse to the tapering of the sidewalls of the contact.

### BACKGROUND

The present invention generally relates to the field of microelectronic, and more particularly to formation of a negative tapered contact formed next to a gate contact.

As gate pitch scales for CMOS technology, non-planar device architecture, such as FinFET or nanosheet device are introduced to mitigate the short channel effect. However, FinFET or nanosheet technology has still shown issues when scaling down such that as the devices become smaller and closer together, they are interfering with each other. Furthermore, as the devices become smaller and closer together forming the contacts can lead to spacing issues with adjacent components, which can lead to shorts.

### BRIEF SUMMARY

Additional aspects and/or advantages will be set forth in part in the description which follows and, in part, will be apparent from the description, or may be learned by practice of the invention.

A microelectronics device including a gate region located adjacent to a source/drain region. A contact located above the source/drain region, where the contact has a bottom section, a middle section and top section, wherein the sidewalls of the bottom section, the middle section, and the top section of the contact are tapered towards a center Y-axis of the contact. A gate contact located above the gate region, where the gate contact has tapered sidewalls towards a center Y-axis of the gate contact. The gate contact is adjacent to the contact, The tapering of the sidewalls of the gate contact is inverse to the tapering of the sidewalls of the contact.

A microelectronic device including a gate region located adjacent to a source/drain region. A gate spacer located between the gate region and the source drain region. A contact located above the source/drain region, where the contact has a bottom section, a middle section and top section. The sidewalls of the bottom section, middle section, and the top section of the contact are tapered towards a center Y-axis of the contact. A first interlayer dielectric located between the gate spacer and the contact. A second interlayer dielectric located above the gate spacer and the gate region, wherein the middle section of the contact is directly contact with the first interlayer dielectric and the second interlayer dielectric.

A method including forming a gate region on a substrate and forming a source/drain region adjacent to the gate region. Forming an interlayer dielectric layer above the source drain region. Forming a first trench in the interlayer dielectric layer, where the first trench as a first width. Forming a second trench by utilizing an angled reactive ion etching process to widen the first trench, where width of the second trench narrows from the bottom of the second trench to the top of the second trench, where the sidewalls of the send trench are tapered towards a century Y-axis.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross section of the nano device after the formation of a gate, in accordance with the embodiment of the present invention.

FIG. 2 illustrates a cross section of the nano device after the formation of a second interlayer dielectric and a hardmask, in accordance with the embodiment of the present invention.

FIG. 3 illustrates a cross section of the nano device after the formation of a lithography layer and first trench, in accordance with the embodiment of the present invention.

FIG. 4 illustrates a cross section of the nano device after the removal of a lithography layer and after formation of the second trench, in accordance with the embodiment of the present invention.

FIG. 5 illustrates a cross section of the nano device after the formation of a contact liner, in accordance with the embodiment of the present invention.

FIG. 6 illustrates a cross section of the nano device after the formation of a contact, in accordance with the embodiment of the present invention.

FIG. 7 illustrates a cross section of the nano device after the removal of the hardmask, in accordance with the embodiment of the present invention.

FIG. 8 illustrates a cross section of the nano device after the formation of the third dielectric layer, a second contact, a third contact, and a metal line, in accordance with the embodiment of the present invention.

FIG. 9 illustrates a cross section of the nano device after the formation of the third dielectric layer, a second contact, a third contact, and a metal line, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a contact for the source/drain with enough spacing between the gate and the contact to prevent shorting. Furthermore, the distance between the contact for the source/drain and the contact for the gate is large enough to prevent the contacts from shorting each other. After an initial source/drain contact trench is formed, the trench is widen using an angled reactive ion etching (RIE) process. The angled RIE process ensures that the trench will have a wider bottom than the opening. Thus, when the trench is filled with a conductive metal, then the spacing between the contact and the top of the gate will be large enough to avoid shorting.

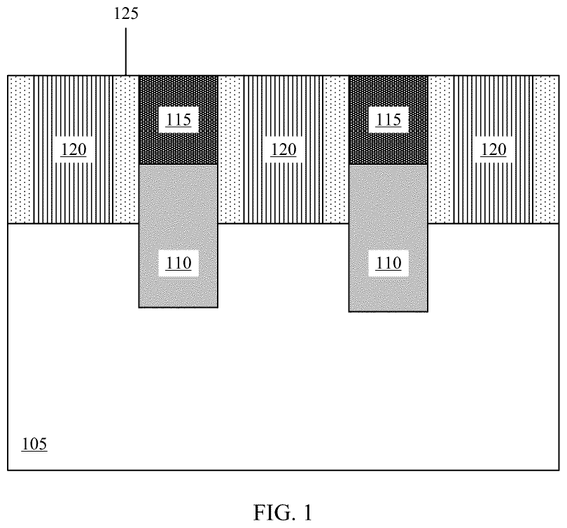

FIG. 1 illustrates a cross section of the nano device after the formation of a gate 120, in accordance with the embodiment of the present invention. The nano device includes a substrate 105, a source drain 110, an interlayer dielectric 115, a gate 120, and a gate spacer 125. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein. The device shown in FIG. 1 can be a planar device, or FinFET device. Please note that the invention applies to other type of devices, such as nanosheet, nanowire, etc.

The source/drain 110 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. The gate 120 can be either formed by gate first or replacement gate process, and is comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The gate 120 is sandwiched between sections of the gate spacers 125. The source/drain 110 and the interlayer dielectric 115 sandwiched between sections of the gate spacer 125, where each section of the gate spacer 125 is located adjacent to different sections of the gate 120.

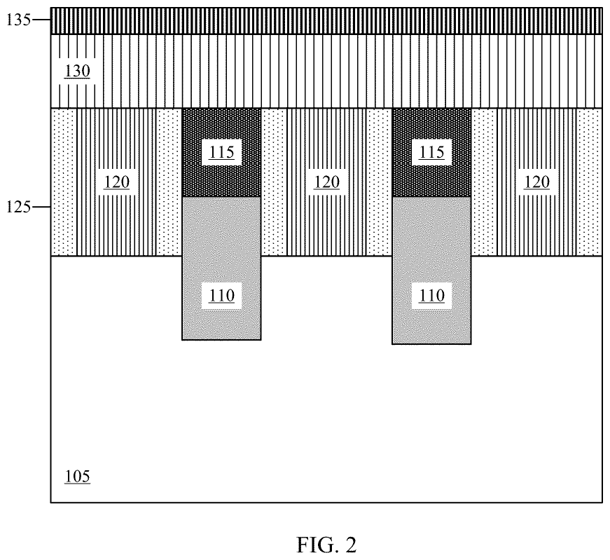

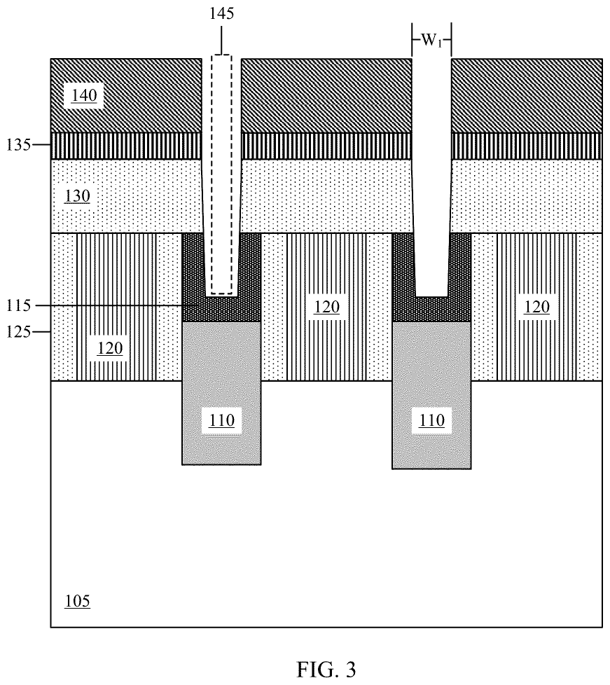

FIG. 2 illustrates a cross section of the nano device after the formation of a second interlayer dielectric 130 and a hardmask 135, in accordance with the embodiment of the present invention. A second interlayer dielectric 130 is formed on the top surfaces of the gate spacer 125, the gate 120, and the interlayer dielectric 115. The second interlayer dielectric 130 can be the same material as the first interlayer dielectric 115 or it can be a different material. A hardmask 135 is formed on the top surface of the second interlayer dielectric 130. FIG. 3 illustrates a cross section of the nano device after the formation of a lithography layer 140 and a first trench 145, in accordance with the embodiment of the present invention. A lithography layer 140 is formed on top of the hardmask 135. The first trench 145 is formed by patterning the lithography layer 140 and etching the underlying layers. The first trench 145 extends downwards through the lithography layer 140, the hardmask 135, and the second interlayer dielectric 130. Furthermore, the first trench 145 extends into the interlayer dielectric 115 but does not extend through the interlayer dielectric 115. As illustrated by the cross section shown in FIG. 3, the interlayer dielectric 115 has a U-shape. The interlayer dielectric 115 forms the bottom surface of the first trench 145 and forms a portion of the sidewalls of the first trench 145. The first trench 145 has a width W₁.

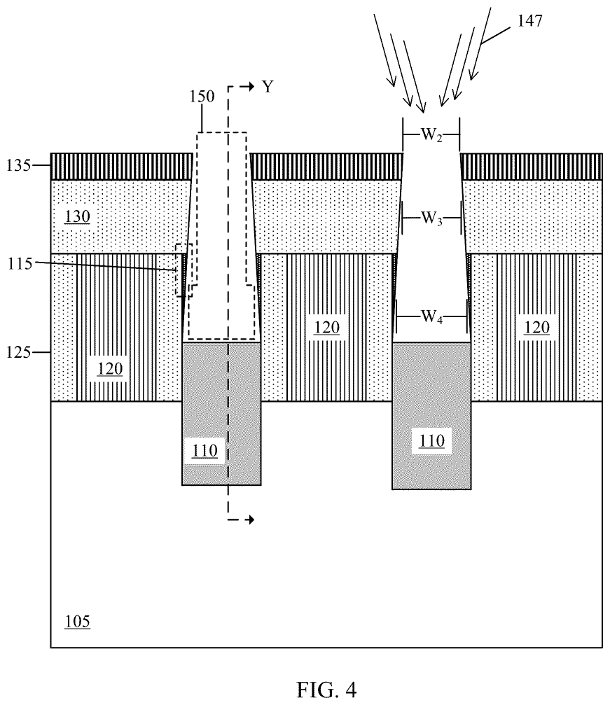

FIG. 4 illustrates a cross section of the nano device after the removal of a lithography layer 140 and after formation of the second trench 150, in accordance with the embodiment of the present invention. The lithography layer 140 is removed. The second trench 150 is created by the widening of the first trench 145. An angled reactive ion etching (RIE) process 147 is used to widen the first trench 145, such that the bottom of the second trench 150 is wider than the top of the second trench 150. For example, the top of the second trench 150 has a width W₂, the middle of the second trench 150 has a width W₃, and the bottom of the second trench 150 has a width W₄. The width of the first trench 145 and the second trench 150 have the following relationship W₁<W₂<W₃<W₄. A portion of the interlayer dielectric 115 remains after the RIE process 147 to widen the first trench 145. The interlayer dielectric 115, the second interlayer dielectric 130, and the hardmask 135 formed the sidewalls of the second trench 150, such that the sidewalls are tapered in the direction of the indicated Y axis in FIG. 4. The second trench 150 exposes the top surface of the source/drain 110.

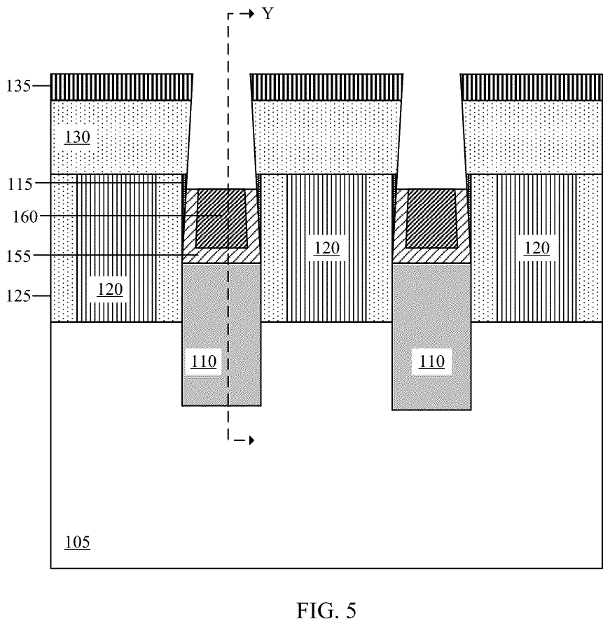

FIG. 5 illustrates a cross section of the nano device after the formation of a contact liner 155, in accordance with the embodiment of the present invention. A contact liner 155 is formed on the exposed surface of the hardmask 135, formed on the sidewalls of the trench 150, and formed on the exposed surface of the source/drain 110. A sacrificial layer 160 (e.g., optical planarization layer) is deposited on the surface of the contact liner 155. The sacrificial layer 160 is then recessed, and the exposed contact liner 155 is etched away to remove most of the contact liner 155 at top. A portion of the contact liner 155 is protected by a portion of the sacrificial layer 160. The contact liner 155 remains located in the bottom section of the second trench 150, such that the contact liner 155 extends along the bottom of the second trench 150 and extends up a portion of the sidewalls. The vertical sections of the contact liner 155 are angled towards the center Y-axis because of the tapered/angled sidewalls of the trench 150. As illustrated by FIG. 5, the contact liner 155 has a U-shape. The contact liner 155 can be comprised of, for example, a metal liner such as Ti, Ni, or NiPt, with optional additional adhesion metal liner on top, such as TiN.

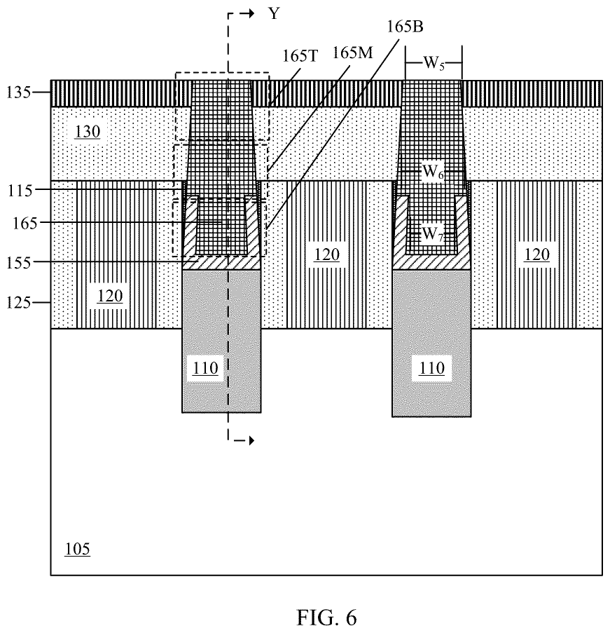

FIG. 6 illustrates a cross section of the nano device after the formation of a contact 165, in accordance with the embodiment of the present invention. The sacrificial layer 160 is removed to create a void between the vertical sections of the contact liner 155. A contact 165 is formed by filling the second trench 150 with a conductive metal. The contact 165 is located within the space of the contact liner 155, such that material of contact 165 mushrooms over the top of the contact liner 155 to fill second trench 150. The contact liner 155 causes the section of the contact 165 contained within the contact liner 155 to have a first taper/angled towards the center Y axis. The top surface of the vertical sections of the contact liner 155 creates a shoulder/shelf for a portion of the contact 165. At least three sides of a bottom section 165B of the contact 165 is in direct contact with the contact liner 155. The contact liner 155 causes the sidewalls of the bottom section of the contact 165 to be in contact with a bottom surface of the middle section of the contact 165. This means the sidewalls of the bottom section of the contact 165 are not continuous with the sidewalls of the middle section of the contact 165. The middle section 165M of the contact 165 is in contact with a top surface of the vertical sections of the contact liner 155, the interlayer dielectric 115, and the second interlayer dielectric 130. Because the second trench 150 width varies, i.e., the width of the second trench 150 narrows towards the top of the second trench 150, therefore, the width of the contact 165 narrows towards the top of the contact 165. This means the top section 165T of the contact 165 has a narrower width W₅ than the width W₆ of the middle section of the contact 165. The width of the top section 165T of the contact 165 can be equal to, less than, or greater than the width W₇ of the bottom section of the contact 165 (i.e., the section of the contact 165 surrounded by the contact liner 155). The middle section 165M and the top section 165T of the contact 165 are tapered/angled to the center Y-axis of the contact 165. The tapering/angle of the middle section 165M and top section 165T of the contact 165 can be the equal to, less than, or greater than the tapering/angle of the bottom section 165B of the contact 165 contained within the contact liner 155. The contact 165 may comprise metals such as Ru, W, Co, with an optional thin adhesion liner, such as TiN.

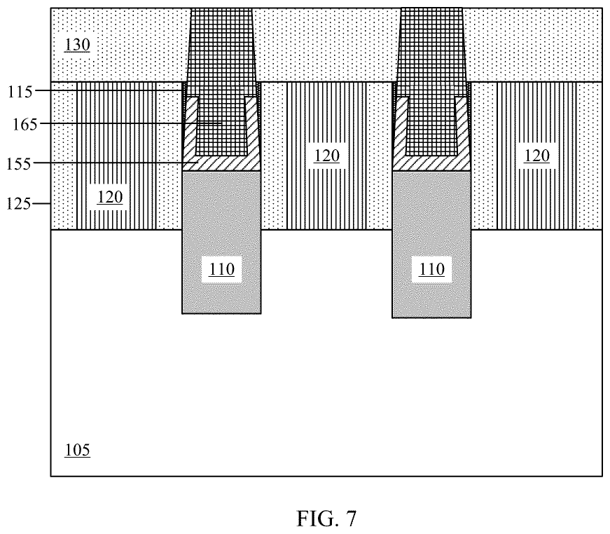

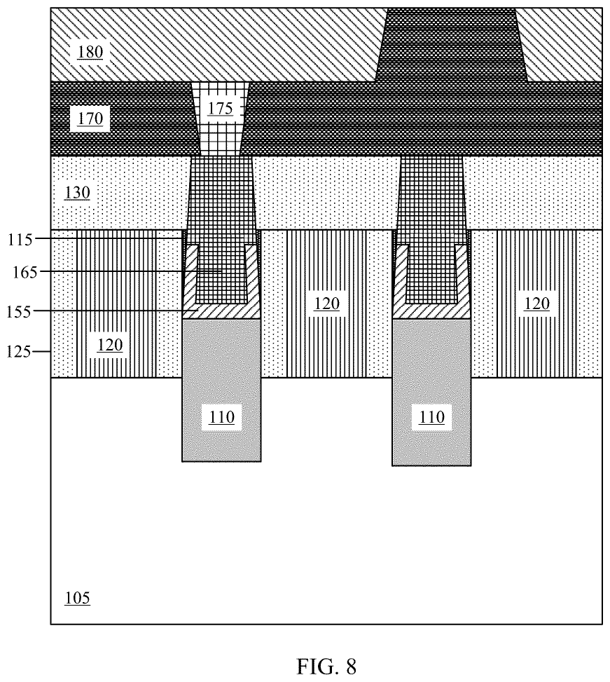

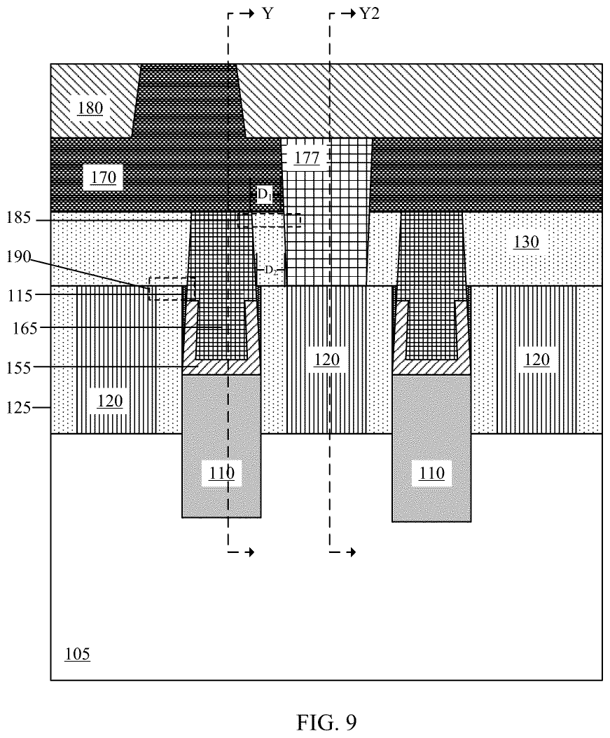

FIG. 7 illustrates a cross section of the nano device after the removal of the hardmask 135 and top portion of the contact 165, by e.g., CMP, in accordance with the embodiment of the present invention. FIGS. 8 and 9 illustrates a cross section of the nano device after the formation of the third dielectric layer 170, a second contact 175, a third contact 177, and a metal layer 180, in accordance with the embodiment of the present invention. The hardmask 135 is removed to expose the top surface of the second interlayer dielectric 130 and a top surface of the contact 165 is exposed. A dielectric layer 170 is formed on top of the second interlayer dielectric 130 and on top of the contact 165. A second contact 175 is formed in the dielectric layer 170. The bottom surface of the second contact 175 is connected to the contact 165 and the top surface of the second contact 175 is connected to a metal layer 180. The metal layer 180 is formed on top of the dielectric layer 170.

A third contact 177 or the gate contact is formed in the dielectric layer 170 and the second interlayer dielectric 130, such that the bottom surface of the third contact 177 is connected to gate 120 and the top surface of the third contact 177 is connected to the metal layer 180. The sidewalls of the third contact 177 is tapered to the center axis Y2 of the third contact. The tapering of the sidewalls of the third contact 177 is an inverse tapering of the side walls of the contact 165. Meaning as the third contact 177 get narrower towards the gate 120, while the contact 165 get narrower as it extends vertically through the second interlayer dielectric 130. The distance D₁ is the distance between the top of the contact 165 and the sidewall of the third contact 177. The distance D₂ is the distance between the middle section 165M and the bottom of the third contact 177. The inverse tapering relationship between the contact 165 and the third contact 177 ensures that the distances D₁ and D₂ are large enough to prevent shorting between the contact 165 and the third contact 177.

By widening the first trench 145 with an angled RIE process 147 to form the second trench 150 ensures that the gate 120 and the contact 165 will not short each other. This is accomplished by the narrowing of the top section of the trench 150 which ensures that distance between the top of the gate 120 and the contact 165 is large enough to prevent the shorting. As illustrated by dashed box 190 the distance is large enough between the contact 165 and the gate 120 to ensure that contact 165 does not short the gate 120 or have any reliability problem like soft leakage or dielectric breakdown between the contact 165 and gate 120. This achieved by the fact that the widest portion of the contact 165 is located between sections of the gate spacer 125 and the interlayer dielectric 115. The dashed box 190 further illustrates that the middle section 165M of the contact 165 is in contact with two different dielectric layers (i.e., the second interlayer dielectric 130 and the first interlayer dielectric 115). Furthermore, as the contact 165 extends vertically, the width of the contact 165 decreases, i.e., the sidewalls of the contact 165 are angled/tapered towards the Y axis. Meaning that the sidewalls of the contact 165 are tapered/angled towards the vertical center of the contact. The narrowing of the contact 165 ensures that there will be enough space between the contact 165 and the third contact 177 to prevent shorts or any reliability problem as highlighted in 185.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronics device comprising:
a gate region located adjacent to a source/drain region; and
a contact located above the source/drain region, wherein the contact has a bottom section, a middle section and top section, wherein the sidewalls of the bottom section, the middle section, and the top section of the contact are tapered towards a center Y-axis of the contact;
a gate contact located above the gate region, wherein the gate contact has tapered sidewalls towards a center Y-axis of the gate contact, wherein the gate contact is adjacent to the contact, wherein the tapering of the sidewalls of the gate contact is inverse to the tapering of the sidewalls of the contact.

2. The microelectronics device of claim 1, wherein the bottom section of the contact has a first width, the middle section of the contact has a second width, and top section of the contact has a third width.

3. The microelectronics device of claim 2, wherein the first width is less than the second width.

4. The microelectronic device of claim 3, wherein the third width is less than the second width.

5. The microelectronic device of claim 4, wherein the third width is less than, equal to, or greater than the first width.

6. The microelectronics device of claim 1, further comprising:
a contact liner located between the source/drain region and the contact.

7. The microelectronics device of claim 6, wherein the contact liner includes a bottom section that is located directly on top of the source/region, and wherein the contact liner includes a plurality of vertical sections that are angled towards the center Y-axis of the contact.

8. The microelectronics device of claim 7, wherein the bottom section of the contact is located within a space between the plurality of vertical sections of the contact liner and the bottom section of the contact liner.

9. The microelectronics device of claim 8, wherein the middle section of the contact is connected to the bottom section of the contact, and wherein the middle section of the contact is in direct contact with a top surface of the plurality vertical sections of the contact liner.

10. A microelectronic device comprising:
a gate region located adjacent to a source/drain region;
a gate spacer located between the gate region and the source drain region;
a contact located above the source/drain region, wherein the contact has a bottom section, a middle section and top section, wherein the sidewalls of the bottom section, middle section, and the top section of the contact are tapered towards a center Y-axis of the contact;
a first interlayer dielectric located between the gate spacer and the contact; and
a second interlayer dielectric located above the gate spacer and the gate region, wherein the middle section of the contact is directly contact with the first interlayer dielectric and the second interlayer dielectric.

11. The microelectronics device of claim 10, wherein the bottom section of the contact has a first width, the middle section of the contact has a second width, and top section of the contact has a third width.

12. The microelectronics device of claim 11, wherein the first width is less than the second width.

13. The microelectronic device of claim 12, wherein the third width is less than the second width.

14. The microelectronic device of claim 13, wherein the third width is less than, equal to, or greater than the first width.

15. The microelectronics device of claim 10, further comprising:
a contact liner located between the source/drain region and the contact, wherein the contact liner is adjacent to the gate spacer, and wherein the contact liner is adjacent to the interlayer dielectric.

16. The microelectronics device of claim 15, wherein the contact liner includes a bottom section that is located directly on top of the source/region, and wherein the contact liner includes a plurality of vertical sections that are angled towards the center Y-axis of the contact.

17. The microelectronics device of claim 16, wherein the bottom section of the contact is located within a space between the plurality of vertical sections of the contact liner and the bottom section of the contact liner.

18. The microelectronics device of claim 17, wherein the middle section of the contact is connected to the bottom section of the contact, and wherein the middle section of the contact is in direct contact with a top surface of the plurality vertical sections of the contact liner.

19. A method comprising:
forming a gate region on a substrate;
forming a source/drain region adjacent to the gate region;
forming an interlayer dielectric layer above the source drain region;
forming a first trench in the interlayer dielectric layer, wherein the first trench as a first width; and
forming a second trench by utilizing an angled reactive ion etching process to widen the first trench, wherein width of the second trench narrows from the bottom of the second trench to the top of the second trench, wherein the sidewalls of the send trench are tapered towards a century Y-axis.

20. The method of claim 19, further comprising
forming a contact located about the source/drain region, wherein the contact has a bottom section, a middle section and top section, wherein the sidewalls of the bottom section of the contact are tapered towards a center Y-axis of the contact, and the sidewalls of the of the middle section of the contact are tapered towards the center Y-axis of the contact, wherein the sidewalls of the bottom section of the contact are not continuous with the sidewalls of the middle section of the contact.
